(19) United States
(12) Patent Application Publication
(10) Pub. No.: US 2005/0257546 A1
(43) Pub. Date: Nov. 24, 2005

(54) Cooling device controlling apparatus, cooling device failure detecting apparatus, cooling device failure detecting method, and computer readable recording medium recording program for causing computer to execute detection of failure of cooling device capable of detecting failure in short period efficiently

(75) Inventor: Teruo Ishishita, Nishikamo-gun (JP)

Correspondence Address: OLIFF & BERRIDGE, PLC, P.O. BOX 19928, ALEXANDRIA, VA, 22320, US

(73) Assignee: TOYOTA JIDOSHA KABUSHIKI KAISHA, Toyota-shi (JP)

(21) Appl. No.: 11/080,912

(22) Filed: Mar. 16, 2005

(30) Foreign Application Priority Data
May 20, 2004 (JP) 2004-150263

(51) Int. Cl. F25B 27/00; H05K 7/20; B60H 1/32

(52) U.S. Cl. 62/236; 62/239

(57) ABSTRACT

After a vehicle system is actuated, a mode command unit determines that an auxiliary battery is cleared. Determining that the auxiliary battery is cleared because of loss of stored information of backup RAM, the mode command unit outputs a cooling mode command signal SI specifying a prescribed cooling mode to a fan circuit, and starts measuring a prescribed time with a timer. The fan circuit drives a fan motor with a prescribed cooling mode and detects a number of rotations of the fan motor to transmit to the mode command unit as a fan output signal. The mode command unit detects a failure of a cooling fan from a comparison result of the fan output signal and the specified prescribed cooling mode. The timer senses a lapse of the prescribed time, and the failure detection ends.

This nonprovisional application is based on Japanese Patent Application No. 2004-150263 filed with the Japan Patent Office on May 20, 2004, the entire contents of which are hereby incorporated by reference.

### BACKGROUND OF THE INVENTION

1. Field of the Invention

The present invention relates to a cooling device controlling apparatus that controls a cooling device for an electric unit mounted on a vehicle, and particularly, to a cooling device failure detecting apparatus and a cooling device failure detecting method for detecting a failure of a cooling device, and to a computer readable recording medium recording a program for causing a computer to execute detection of a failure of a cooling device.

2. Description of the Background Art

Generally, in a vehicle such as an EV (Electric Vehicle) or an HV (Hybrid Vehicle), the drive power from electric energy is obtained by converting DC (Direct Current) power supplied from a main battery of high voltage to three-phase AC (Alternating Current) power with an inverter and thereby rotating a three-phase AC motor. When decelerating the vehicle, conversely, regenerative energy obtained through regeneration by the three-phase AC motor is stored in the main battery, making full use of the energy for driving.

In addition to the main battery of high voltage, the vehicle further incorporates an auxiliary battery for supplying electric power to auxiliary electric components such as a lighting device, an ignition device and a motor pump. The auxiliary battery is charged with electric power generated by an alternator, or with electric power from the main battery. In particular, when the auxiliary battery is charged with electric power from the main battery, the voltage is lowered by a DC/DC converter.

As such a main battery, a Nickel-Metal hydride cell, a lithium ion cell or the like is mainly employed. Accordingly, when the main battery is charged, the heat of reaction due to a chemical reaction occurs and the cell temperature increases. The increase in the cell temperature causes deterioration of cell performance and cell life. Therefore, in order to suppress the increase in the cell temperature, means for cooling the main battery is required. As to the inverter and the DC/DC converter also, cooling is required as heat is generated by a power element.

Accordingly, the vehicle incorporates a cooling fan for cooling the main battery, the inverter and the DC/DC converter. Generally, the cooling fan is configured to actuate sensing the temperature of a cooling target, such as the main battery, and to adjust the cooling target to fall within a prescribed temperature range.

There may be a failure of the cooling fan such as disconnection or melting of a connection. There may be a failure of control of the cooling fan. With such a failure, the cooling ability of the cooling fan is inhibited, and the main battery is hardly kept in an appropriate condition.

As means for detecting a failure of a cooling fan, for example as disclosed in Japanese Patent Laying-Open No. 2002-343449, a method has been proposed wherein a difference between a cell temperature when control to actuate cooling fan is provided and a cell temperature when control to stop cooling fan is provided is compared with a prescribed threshold value, to determine whether the cooling fan is normal or there is a failure.

Japanese Patent Laying-Open No. 2001-86601 discloses a cooling fan failure sensing apparatus that includes estimated temperature change value calculate means for calculating an estimated temperature change value of a cell based on an amount of heat generated by the cell and the cooling ability of a cooling fan, actual temperature change value calculate means for calculating an actual temperature change value of the cell, and failure sense means for sensing a failure of the cooling fan based on a result of comparing the calculated estimated temperature change value and actual temperature change value.

Japanese Patent Laying-Open No. 11-252808 discloses a method wherein a driving process of a hybrid system is initiated and a battery storage amount is calculated, and thereafter a fan failure determination process is performed, so that the result of the fan failure determination process is reflected on charging/discharging power of the battery, thereby preventing deterioration of the battery caused by an unexpected decrease or increase in the temperature of the battery.

On the other hand, according to the methods for detecting a failure of a cooling fan described above, since a change in the battery temperature is employed as an index for a failure detection determination, a failure of the cooling fan cannot be detected unless the vehicle system is actuated to drive the motor and the battery is caused to operate normally.

Accordingly, for detecting a failure of the cooling fan, a prescribed time has been required, at least from the actuation of the vehicle system until a state is entered where the battery temperature is increased to a certain degree. Therefore, it has been difficult to perform failure detection efficiently at shipment from a factory or at a repair service.

Further, with the conventional methods for detecting a failure of a cooling fan, sometimes detection is performed with unduly frequency, since a detection operation is performed every time the vehicle system is actuated. Also in those cases, it has been required to improve efficiency of the failure detection.

### SUMMARY OF THE INVENTION

Accordingly, an object of the present invention is to provide a cooling device controlling apparatus capable of detecting a failure of a cooling fan in a short period efficiently.

Another object of the present invention is to provide a cooling device failure detecting apparatus and a cooling device failure detecting method capable of detecting a failure of a cooling fan in a short period efficiently.

Still another object of the present invention is to provide a computer readable recording medium recording a program for causing a computer to execute detection of a failure of a cooling device capable of detecting a failure of a cooling fan in a short period efficiently.

According to one aspect of the present invention, a cooling device controlling apparatus controlling a cooling device for an electric unit mounted on a vehicle is provided. The electric unit includes a first power source, an electric power converter converting a direct current voltage of the first power source to drive a motor, and a second power source receiving a supply of electric power from the first power source to be charged. The cooling device controlling apparatus includes: a cooling device control unit for controlling a supply amount of a cooling medium of the cooling device based on temperature information of the electric unit; and a cooling device failure detect unit for detecting a failure of the cooling device in accordance with initialization of the second power source.

Preferably, the cooling device failure detect unit detects a failure of the cooling device after the second power source is replaced with a new second power source.

Preferably, the initialization of the second power source is initialization caused by replacement of the second power source.

Preferably, the cooling device control unit includes a initialization determine unit for determining whether or not the second power source is initialized, a mode command unit for outputting to the cooling device a mode command specifying one mode selected out of a plurality of modes each specifying a supply amount, being different from one another, of the cooling medium based on a determination result of the initialization determine unit and temperature information of the electric unit, and a timer for measuring an output time period of the mode command. When the second power source is determined to be initialized, the mode command unit selects a prescribed mode specifying a supply amount of the cooling medium required for determining a failure of the cooling device and outputs a command of the prescribed mode for a prescribed time period. The cooling device failure detect unit determines a failure of the cooling device based on whether or not a supply amount of a cooling medium of the cooling device is equal to a supply amount of the prescribed mode during the prescribed time period.

Preferably, the cooling device control unit further includes a storage unit for receiving a supply of electric power from the second power source to temporarily store information. The initialization determine unit determines that the second power source is initialized, based on loss of the information in the storage unit.

Preferably, the cooling device includes a cooling medium generate unit for generating the cooling medium in a supply amount specified by the mode command, and a generation amount detect unit for detecting a generation amount of the cooling medium to transmit a detection result to the cooling device failure detect unit.

Preferably, the initialization determine unit determines, on actuation of the vehicle, whether or not the second power source is initialized.

Preferably, the cooling device receives a supply of electric power from the second power source to cool the electric unit.

According to another aspect of the present invention, a cooling device failure detecting apparatus detecting a failure of a cooling device cooling an electric unit mounted on a vehicle is provided. The electric unit includes a first power source, an electric power converter converting a direct current voltage of the first power source to drive a motor, and a second power source receiving a supply of electric power from the first power source to be charged. The cooling device failure detecting apparatus comprises: an initialization determine unit for determining whether or not the second power source is initialized, and a failure detect unit for detecting a failure of the cooling device in accordance with a determination that the second power source is initialized.

Preferably, the failure detect unit detects a failure of said cooling device after said second power source is replaced with a new second power source.

Preferably, the second power source is replaced with a new second power source when a failure of the cooling device is detected.

Preferably, the initialization determine unit determines that the second power source is initialized, based on loss of information temporarily stored with a supply of electric power from the second power source.

Preferably, the failure detect unit includes a mode command unit for outputting to the cooling device a mode command specifying one mode selected out of a plurality of modes each specifying a supply amount, being different from one another, of the cooling medium based on a determination result of the initialization determine unit and temperature information of the electric unit, and a timer for measuring a prescribed time period during which the mode command is output. When the second power source is determined to be initialized, the mode command unit selects a prescribed mode specifying a supply amount of the cooling medium required for determining a failure of the cooling device and outputs a command of the prescribed mode for the prescribed time period. The failure detect unit further includes a failure determine unit for determining a failure of the cooling device based on whether or not a supply amount of a cooling medium of the cooling device is equal to a supply amount of the prescribed mode during the prescribed time period.

Preferably, the initialization determine unit determines, on actuation of said vehicle, whether or not the second power source is initialized.

Preferably, the cooling device receives a supply of electric power from the second power source to cool the electric unit.

According to still another aspect of the present invention, a cooling device failure detecting method for detecting a failure of a cooling device cooling an electric unit mounted on a vehicle is provided. The electric unit includes a first power source, an electric power converter converting a direct current voltage of the first power source to drive a motor, and a second power source receiving a supply of electric power from the first power source to be charged. The cooling device failure detecting method includes: an initialization determine step of determining whether or not the second power source is initialized; and a failure detect step of detecting a failure of the cooling device in accordance with a determination that the second power source is initialized.

Preferably, the failure detect step includes a step of detecting a failure of the cooling device after the second power source is replaced with a new second power source.

Preferably, the cooling device failure detecting method further includes a step of replacing the second power source with a new second power source.

Preferably, the initialization determine step includes a step of determining that the second power source is initialized, based on loss of information temporarily stored with a supply of electric power from the second power source.

Preferably, the failure detect step includes a mode command step of outputting to the cooling device a mode command specifying one mode selected out of a plurality of modes each specifying a supply amount, being different from one another, of the cooling medium based on a determination result of the initialization determine step and temperature information of the electric unit, and a step of measuring a prescribed time period during which the mode command is output. The mode command step includes a step of selecting, when the second power source is determined to be initialized, a prescribed mode specifying a supply amount of the cooling medium required for determining a failure of the cooling device and outputting a command of the prescribed mode for the prescribed time period. The failure detect step further includes a failure determine step of determining a failure of the cooling device based on whether or not a supply amount of a cooling medium of the cooling device is equal to a supply amount of the prescribed mode during the prescribed time period.

Preferably, the initialization determine step includes a step of determining, on actuation of the vehicle, whether or not the second power source is initialized.

Preferably, the cooling device receives a supply of electric power from the second power source to cool the electric unit.

According to still another aspect of the present invention, a computer readable recording medium recording a program for causing a computer to execute detection of a failure of a cooling device cooling an electric unit mounted on a vehicle is provided. The electric unit includes a first power source, an electric power converter converting a direct current voltage of the first power source to drive a motor, and a second power source receiving a supply of electric power from the first power source to be charged. The computer readable recording medium recording a program for causing a computer to execute: an initialization determine step of determining whether or not the second power source is initialized; and a failure detect step of detecting a failure of the cooling device in accordance with a determination that the second power source is initialized.

Preferably, the failure detect step includes a step of detecting a failure of the cooling device after the second power source is replaced with a new second power source.

Preferably, the computer readable recording medium further causes the computer to execute a step of replacing the second power source with a new second power source.

Preferably, the initialization determine step includes a step of determining that the second power source is initialized, based on loss of information temporarily stored with a supply of electric power from the second power source.

Preferably, the failure detect step includes a mode command step of outputting to the cooling device a mode command specifying one mode selected out of a plurality of modes each specifying a supply amount, being different from one another, of the cooling medium based on a determination result of the initialization determine step and temperature information of the electric unit, and a step of measuring a prescribed time period during which the mode command is output. The mode command step includes a step of selecting, when the second power source is determined to be initialized, a prescribed mode specifying a supply amount of the cooling medium required for determining a failure of the cooling device and outputting a command of the prescribed mode for the prescribed time period. The failure detect step further includes a failure determine step of determining a failure of the cooling device based on whether or not a supply amount of a cooling medium of the cooling device is equal to a supply amount of the prescribed mode during the prescribed time period.

Preferably, the initialization determine step includes a step of determining, on actuation of the vehicle, whether or not the second power source is initialized.

Preferably, the cooling device receives a supply of electric power from the second power source to cool the electric unit.

According to the present invention, the failure detection of a cooling fan is performed only at a timing when an auxiliary battery is initialized, such as at shipment from a factory or at a repair service, and not performed until the next initialization of the auxiliary battery. Therefore, the frequency of performing failure detection is minimized, and the failure detection can be performed efficiently.

Further, by setting the timing of the failure detection of a cooling fan at a timing when the auxiliary battery is replaced with a new one, the full performance of the auxiliary battery to be a precondition is ensured, whereby the accuracy of detecting a failure of the cooling fan is improved and the performance of the cooling fan can be maintained at a constant level.

Still further, as the failure detection of a cooling fan is performed at a prescribed time of an early stage after actuation of a vehicle system, the failure detection can be performed in a short period as compared to conventional failure detecting methods performing the failure detection by detecting the battery temperature.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a schematic block diagram of a motor driving device according to an embodiment of the present invention.

FIG. 2 is a control block diagram related to a description of control of a cooling fan by a battery ECU in FIG. 1.

FIG. 3 is a circuit diagram showing a detailed configuration of a fan circuit in FIG. 2.

FIG. 4 is a flowchart for describing a failure detection operation of a cooling fan in the motor driving device.

FIG. 5 shows one exemplary specific control program of the failure detection operation of the cooling fan shown in FIG. 4.

### DESCRIPTION OF THE PREFERRED EMBODIMENTS

In the following, an embodiment of the present invention is described in detail referring to the drawings. Throughout the drawings, an identical reference character is allotted to identical or corresponding components.

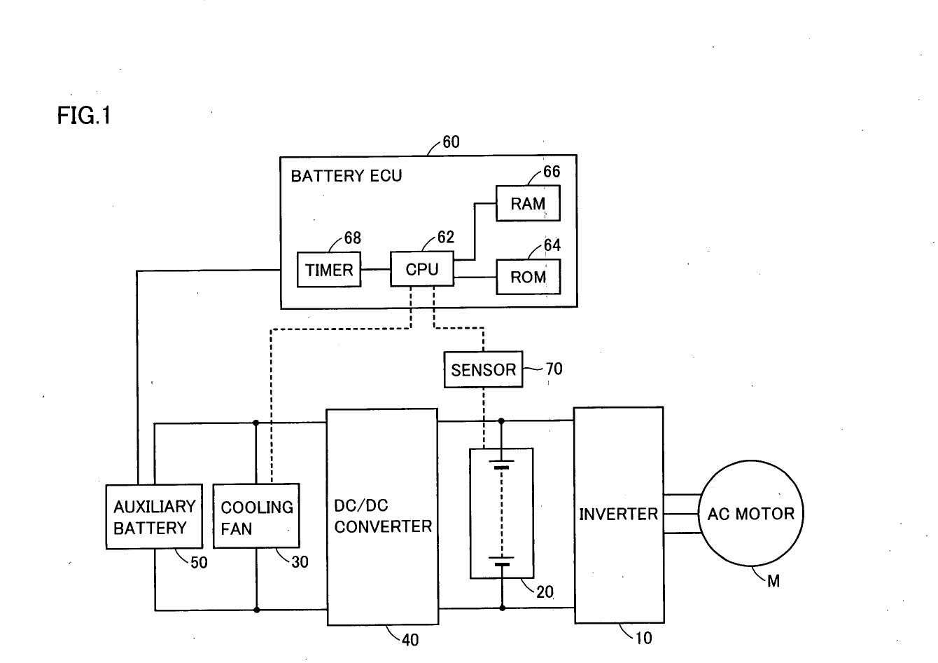

FIG. 1 is a schematic block diagram of a motor driving device according to the embodiment of the present invention.

Referring to FIG. 1, the motor driving device includes an inverter 10 supplying an AC motor M with electric power, a main battery 20 supplying electric power through inverter 10, a cooling fan 30, a DC/DC converter 40, an auxiliary battery 50, and a battery ECU (Electrical Control Unit) 60 controlling charging/discharging of the battery.

AC motor M is a driving motor for producing torque for driving the driving wheels of a hybrid vehicle or an electric vehicle. Alternatively, in a hybrid vehicle, AC motor M may not be a motor that drives the driving wheels, but it may be the one that has a function of a generator driven by the engine and that operates as an electric motor to the engine, and that is capable of, for example, starting the engine.

Main battery 20 has a configuration in which a number of Nickel-Metal hydride cells, for example, are serially connected. Main battery 20 may also be lead-acid cells, lithium ion cells, capacitors or fuel-cells.

Inverter 10 is a three-phase inverter. When DC voltage is supplied from main battery 20, it converts the DC voltage to three-phase AC voltage based on a control signal from a control circuit, which is not shown, to drive AC motor M. Thus, AC motor M is driven to produce a specified torque.

DC/DC converter 40 down-converts DC voltage from main battery 20 and supplies electric power to an auxiliary electric load such as an auxiliary battery 50 and a lighting device, which is not shown. The DC voltage supplied to auxiliary battery 50 charges auxiliary battery 50. Auxiliary battery 50 is, for example, lead-acid cells.

Cooling fan 30 is arranged to cool main battery 20, and auxiliary battery 50 serves as its power source. It is noted that while cooling fain 30 is arranged to cool main battery 20 in the motor driving device according to the present embodiment, it may be arranged to cool, in addition to main battery 20, other electric units (e.g., DC/DC converter 40, inverter 10 or battery ECU 60) with air blown from cooling fan 30.

The motor driving device further includes a sensor 70 for sensing the cell temperature, a voltage between terminals and a charging/discharging current value of main battery 20. Various information sensed by sensor 70 is transmitted to battery ECU 60.

As shown in FIG. 1, battery ECU 60 includes CPU 62 executing a program related to battery control, ROM (Read Only Memory) 64 storing a control program executed at CPU 62, RAM (Random Access Memory) 66 temporarily storing the execution result of the control program, and a timer 68 sensing a lapse of time set in advance.

Battery ECU 60 controls the charging amount of main battery 20 and auxiliary battery 50, and controls the air-blow amount of cooling fan 30 to adjust the cell temperature of main battery 20.

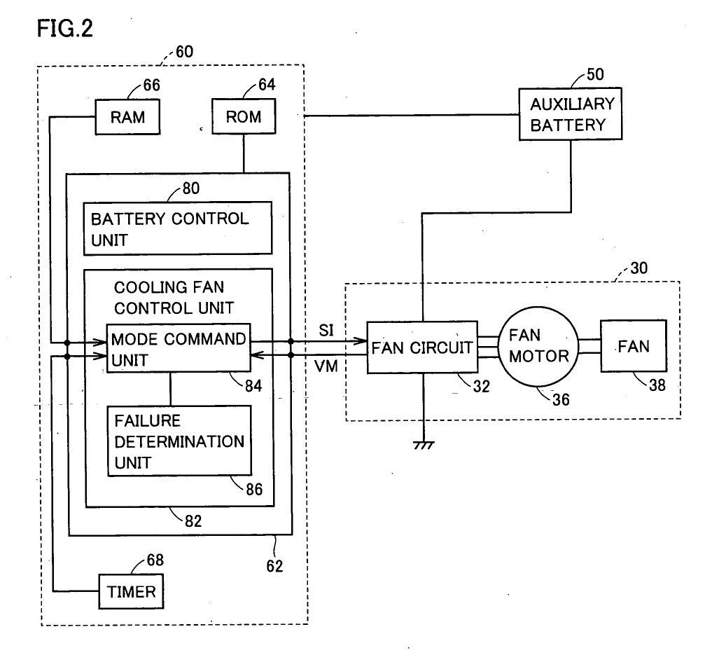

FIG. 2 is a control block diagram related to a description of control of cooling fan 30 by battery ECU 60 in FIG. 1.

Referring to FIG. 2, cooling fan 30 includes a fan 38 blowing cooling air to a cooling target, a fan motor 36 rotating fan 38, and a fan circuit 32 controlling the number of rotations of fan motor 36.

The power source voltage of fan circuit 32 is supply voltage VC from auxiliary battery 50 and ground voltage GND, and fan circuit 32 controls the number of rotations of fan motor 36 based on a cooling mode command signal SI sent from CPU 62 of battery ECU 60. Thus, the air-blow amount of fan 38 changes. Further, fan circuit 32 detects the number of rotations of fan motor 36 and outputs the detection result to CPU 62 as a fan output signal VM.

In battery ECU 60, CPU 62 includes a battery control unit 80 controlling the charging amount of main battery 20 and auxiliary battery 50, and a cooling fan control unit 82 controlling cooling fan 30.

Battery control unit 80 calculates the charging amount of battery based on a voltage between terminals and a charging/discharging current value of the battery detected at sensor 70 in FIG. 1. In accordance with the calculated charging amount of main battery 20, electric power generated by AC motor M is selectively used. For example, if the charging amount is lower than a prescribed value, AC motor M operates as a generator to charge main battery 20. On the other hand, if the charging amount is higher than a prescribed value, AC motor M operates as an electric motor using electric power of battery 20.

Cooling fan control unit 82 includes a mode command unit 84 that generates a cooling mode signal SI for specifying the air-blow amount of fan 38.

Mode command unit 84 determines, in a normal control condition, the air-blow amount of fan 38 based on temperature information of main battery 20 sent from sensor 70 in FIG. 1. Here, in accordance with the temperature of main battery 20, mode command unit 84 selects an appropriate cooling mode from a plurality of cooling modes, in which air-blow amounts are set in stages in advance corresponding to temperature levels of main battery 20. The selected cooling mode is output to fan circuit 32 as cooling mode command signal SI.

Fan circuit 32 drives fan motor 36 to attain the air-blow amount corresponding to the provided cooling mode command signal SI. The number of rotations of fan motor 36 is detected at fan circuit 32 to be frequency-voltage converted, and output to mode command unit 84 as a fan output signal VM. Mode command unit 84 checks whether or not the input fan output signal VM matches the specified cooling mode, and provides feedback control.

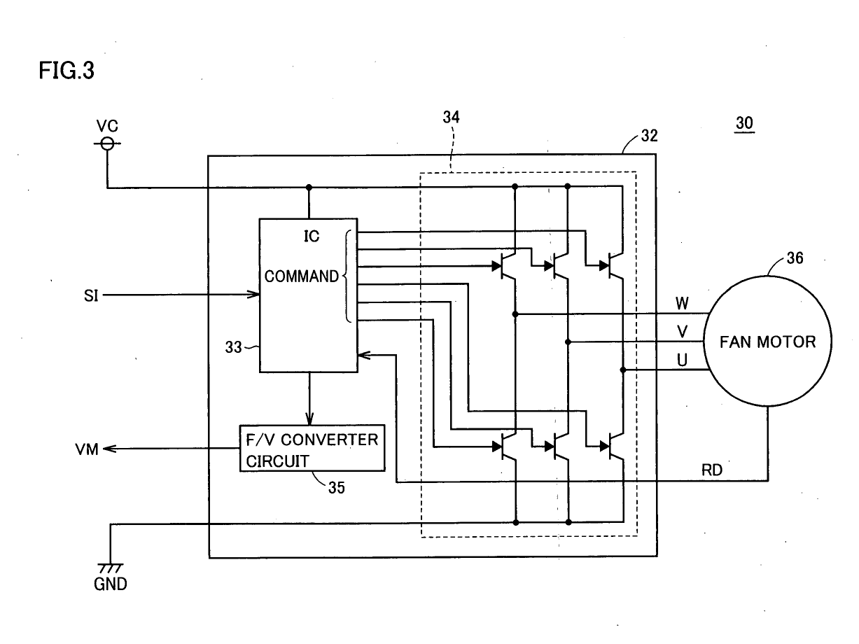

FIG. 3 is a circuit diagram showing a detailed configuration of fan circuit 32 in FIG. 2.

Referring to FIG. 3, fan circuit 32 includes an IC unit 33 generating a control duty command value corresponding to cooling mode command signal SI, an inverter unit 34 outputting three-phase AC voltage based on the control duty command value to drive fan motor 36, and a frequency-voltage converter circuit (hereinafter also referred to as F/V converter circuit) 35 detecting the number of rotations of fan motor 36 to frequency-voltage convert a rotation number detection result signal RD.

Inverter unit 34 converts DC voltage from the auxiliary battery to three-phase AC voltage constituted by U, V and W phases based on the control duty command value from IC unit 33 to drive fan motor 36.

Fan motor 36 is a three-phase AC motor, and causes fan 38 to produce the air-blow in an amount specified by cooling mode command signal SI in accordance with the three-phase AC voltage.

IC unit 33 further detects the number of rotations of fan motor 36 and outputs a rotation number detection signal RD to F/V converter circuit 3 5.

F/V converter circuit 3 5 converts rotation number detection signal RD to a signal of a voltage level corresponding to its frequency. The converted rotation number detection signal RD is transmitted to mode command unit 84.

Referring back to FIG. 2, mode command unit 84 further includes a failure determination unit 86 determining whether or not a failure of cooling fan 30 exists.

As will be described later, in a failure detect operation condition, failure determination unit 86 determines whether or not a failure of cooling fan 30 exists based on fan output signal VM that is fed back from fan circuit 32.

In the following, a method for detecting a failure of cooling fan 30 according to the present embodiment is described. First, characteristic matters of the cooling fan failure detecting method according to the present embodiment are described.

First, the cooling fan failure detecting method according to the present embodiment is primarily characterized in that it is performed as part of a vehicle actuation sequence at an initial stage when the vehicle system is actuated, i.e., when an ignition key (hereinafter also referred to as IG) is switched from off to on.

Next, the cooling fan failure detecting method is secondarily characterized in that it is performed in association with the initialization of auxiliary battery 50 immediately after the actuation of the vehicle system, and that it is not performed until the next initialization of auxiliary battery 50.

Specifically, auxiliary battery 50 is normally in a charged state in preparation for the actuation of the vehicle that is followed by the operation of the motor driving device in FIG. 1. On the other hand, auxiliary battery 50 is in an initialized state, i.e., a so-called clear state when shipped from a factory. Further, when a repair service is provided, the clear state is established by once removing auxiliary battery 50 for maintenance or for replacement because of performance deterioration of auxiliary battery 50 and then mounting auxiliary battery 50 again. The present embodiment employs a configuration in which a cooling fan failure detection operation is performed if such a clear state of auxiliary battery 50 is detected when the vehicle system is actuated. Thus, the failure detection of cooling fan 30 is performed at limited timings such as at shipment from a factory or at a repair service.

Here, determination of whether or not auxiliary battery 50 is in the clear state is performed by sensing that RAM for backup 66, receiving a supply of electric power from auxiliary battery 50 for storing information temporarily, loses the stored information as the power supply is stopped by the initialization of auxiliary battery 50.

At a repair service, the performance of auxiliary battery 50 may be deteriorated. If auxiliary battery 50 mounted again after the maintenance is involved with performance deterioration, cooling fan 30 may not operate with its fill ability given that the failure detection operation to cooling fan 30 is performed using the deteriorated auxiliary battery 50 as the power source.

Accordingly, it is desirable that the detection of failure of cooling fan 30 is performed in a state in which full performance of auxiliary battery 50 to be a precondition is ensured. For example, employing a configuration in which a failure of cooling fan 30 is detected at a timing when auxiliary battery 50 is replaced with a new one, the precondition for the detecting operation may be excellent and uniform, whereby the accuracy of detecting a failure of cooling fan 30 is improved and the performance of cooling fan 30 can be maintained at a constant level.

Therefore, the timing for detecting a failure of a cooling fan according to the present embodiment includes, as one example of an event when auxiliary battery 50 is cleared, when auxiliary battery 50 is replaced with a new one.

Alternatively, employing a configuration in which auxiliary battery 50 is replaced with a new one utilizing the opportunity of the failure detection of cooling fan 30, the performance of auxiliary battery 50 is ensured, whereby the performance of cooling fan 30 afterwards can be maintained at a constant level.

Therefore, the detection of a failure of a cooling fan according to the present embodiment further includes a configuration in which auxiliary battery 50 is replaced with a new one at the timing of performing a failure detection of cooling fan 30.

With such a configuration, as compared to conventional methods for detecting a failure of a cooling fan wherein failure detection of a cooling fan is performed every time a vehicle system is actuated and causing the main battery to operate normally, the frequency of failure detection is decreased and the failure detection can be performed efficiently, and the performance of the cooling fan can be maintained at a constant level.

Next, the cooling fan failure detecting method according to the present embodiment is specifically described.

First, when actuation of the vehicle system is recognized, mode command unit 84 determines whether or not auxiliary battery 50 is cleared. The determination of whether or not auxiliary battery 50 is cleared is performed by checking that stored information of backup RAM 66 is lost. Here, when it is determined that auxiliary battery 50 is cleared, the motor driving device shifts to a failure detection operation of cooling fan 30.

Here, such a configuration may be employed that replacement of auxiliary battery 50 with a new one is detected and the shift to the failure detection operation of cooling fan 30 is performed. Alternatively, such a configuration may be employed that, when it is determined that auxiliary battery 50 is cleared, auxiliary battery 50 is replaced with a new one, and then the shift to the failure detection operation of cooling fan 30 is performed.

Next, the failure detection operation of cooling fan 30 is performed by detecting an operating state of fan motor 36 when cooling fan 30 is operated in a prescribed cooling mode that is set in advance.

Specifically, mode command unit 84 of battery ECU 60 outputs cooling mode command signal SI specifying a prescribed cooling mode to fan circuit 32. To this prescribed cooling mode, a mode for specifying the air-blow amount required for at least detecting a failure of cooling fan 30 is set in advance among the above-described plurality of stages of cooling modes.

Mode command unit 84 starts a time measuring operation with timer 68 in FIG. 2 at a timing when cooling mode command signal SI of prescribed cooling mode is provided to fan circuit 32. Timer 68 is set with a time period necessary and sufficient for completing a failure detection operation, and it counts up the set time period from the time point at which cooling mode command signal SI is output.

Fan circuit 32 drives fan motor 36 in accordance with the specified prescribed cooling mode. Further, it detects the number of rotations of fan motor 36 and transmits it to mode command unit 84 as fan output signal VM. Mode command unit 84 performs a matching comparison operation between fan output signal VM and the specified prescribed cooling mode, and detects a failure such as disconnection or melting in cooling fan 30 based on the matching comparison result.

Specifically, whether or not a failure of cooling fan 30 exists is determined referring to the voltage level of fan output signal VM at failure determination unit 86 within cooling fan control unit 82. For example, in an event where the voltage level of fan output signal VM does not match the voltage level of cooling mode command signal SI, i.e., in an event of so-called characteristic mismatch, it is determined that there is a failure in cooling fan 30. When the voltage level of fan output signal VM is substantially at 0V, it is construed to indicate short-circuiting of a connection of cooling fan 30 due to melting, and hence it is determined that there is a failure. On the other hand, when the voltage level of fan output signal VM is substantially at the maximum voltage, it is construed to indicate an open failure due to disconnection of a connection of cooling fan 30, and hence it is determined that there is a failure. Such a result of detecting a failure is transmitted to a control circuit, which is not shown, and reported to an operator through displaying means that is not shown.

Finally, mode command unit 84 checks detection of a lapse of the prescribed time period set to timer 68, and the cooling fan failure detection operation is completed.

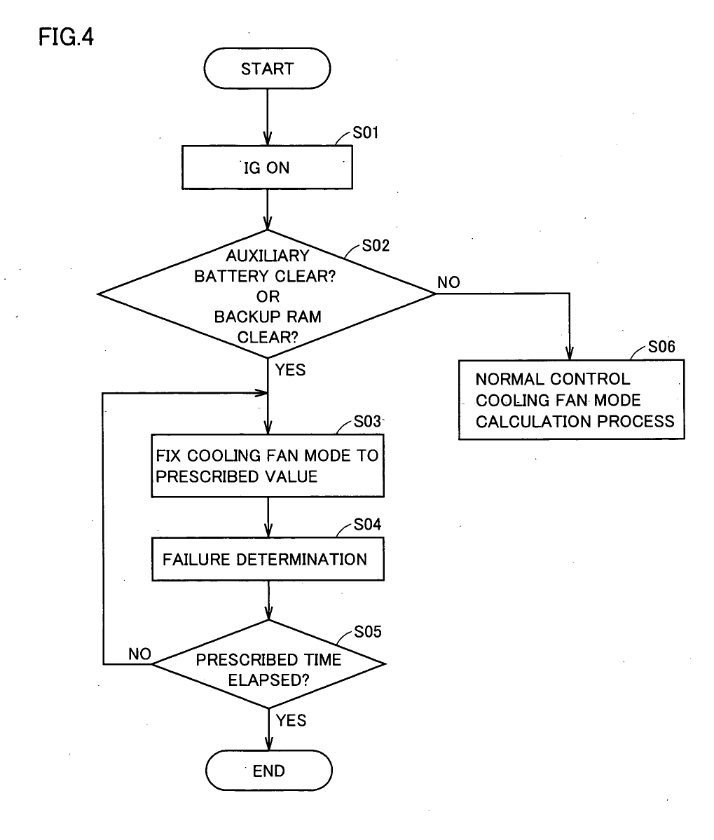

FIG. 4 is a flowchart describing the failure detection operation of cooling fan 30 in the motor driving device in FIG. 1.

Referring to FIG. 4, as the ignition key is turned from off to on and the vehicle system is actuated (step S01), mode command unit 84 within cooling fan control unit 82 determines whether or not the auxiliary battery is cleared (step S02). Here, if it is detected that stored information of backup RAM 66 is lost, it is determined that auxiliary battery 50 is cleared.

At step S02, if it is determined that auxiliary battery 50 is cleared, then mode command unit 84 selects a prescribed cooling fan mode that is set in advance for the failure detection, and outputs cooling mode command signal SI specifying the selected cooling fan mode (step S03). To this prescribed cooling mode, a mode for specifying the air-blow amount required for at least detecting a failure of the cooling fan is set as described below.

On the other hand, if it is determined that auxiliary battery 50 is not cleared at step S02, then mode command unit 84 calculates, as normal control, a cooling fan mode corresponding to the temperature of main battery 20 and outputs the calculation result as mode command signal SI to fan circuit 32 (step S06).

Back to step S03 again, fan circuit 32 of cooling fan 30 receives cooling mode command signal SI specifying the prescribed cooling fan mode and controls the number of rotations of fan motor 36 to attain the air-blow amount specified by the prescribed cooling fan mode. Here, mode command unit 84 starts a time measuring operation of a prescribed set time period with timer 68.

Fan circuit 32 further detects the number of rotations of fan motor 36 and generates fan output signal VM of a voltage level corresponding to the number of rotations, and outputs it to mode command unit 84. Upon detection of characteristic mismatch in the voltage level of fan output signal VM or an open/short-circuiting failure, failure determination unit 86 of cooling fan control unit 82 determines that there is a failure in cooling fan 30 (step S04).

The failure detection operation shown at steps S03 and S04 is performed within a prescribed set time period. Finally, mode command unit 84 detects a lapse of the prescribed set time with timer 68, and the failure detection operation is completed (step S05).

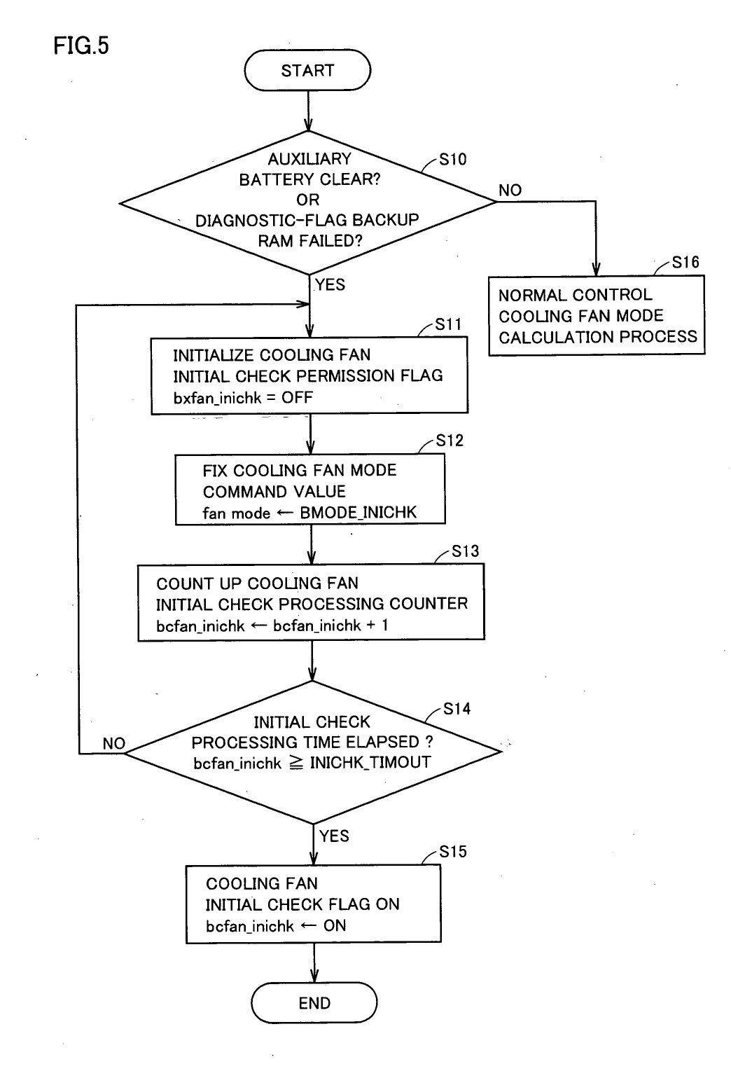

FIG. 5 shows one exemplary specific control program of the failure detection operation of the cooling fan shown in FIG. 4.

Referring to FIG. 5, first, it is determined whether or not auxiliary battery 50 is cleared (step S10). At step S10, if storage information of diagnostic-flag backup RAM is lost, it is determined that auxiliary battery 50 is cleared.

Next, in response to auxiliary batter 50 being cleared, a cooling fan initial check permission flag for performing the failure detection of cooling fan 30 is initialized (step S11). Specifically, cooling fan initial check permission flag bxfan_inichk is set to the initial value OFF. Thus, the motor driving device starts the failure detection operation of cooling fan 30.

In the failure detection operation of cooling fan 30, cooling fan mode command value fanmode is fixed to a prescribed mode BMODE_INICHK (step S 12).

Further, by timer 68, a cooling fan initial check processing counter bcfan_inichk is counted up (step S13). In parallel to this counting operation, according to a failure detection program that is not shown, a process of detecting a failure such as characteristic mismatch or failure of connection state of cooling fan 30 is performed. In response to count value bcfan_inichk of the cooling fan initial check processing counter reaching a prescribed initial check processing time INICHK_TIME, the failure detecting operation is completed (step S14).

Finally, as means for indicating the completion of cooling fan failure detecting process, cooling fan initial check flag bxfan_inichk is validated (ON) (step S15). This cooling fan initial check flag is maintained in the on state unless auxiliary battery 50 is cleared. Therefore, once a failure is detected, then the failure detection operation is not performed at actuation of the vehicle system that follows. Specifically, the next failure detection operation is performed when auxiliary battery 50 is cleared by being removed for maintenance at repairing and mounted again or by being replaced and thereafter the vehicle system is actuated.

As described above, according to the embodiment of the present invention, since a failure detection of a cooling fan is performed only at the timing when the auxiliary battery is initialized such as at shipment from a factory or at a repair service, the frequency of performing failure detection is minimized, and the failure detection can be performed efficiently.

The failure detection of a cooling fan is performed at a prescribed time of an initial stage after the actuation of the vehicle system, and therefore the failure detection can be performed with a shorter determination processing time as compared to conventional failure detecting methods wherein failure determination is performed in a state in which the vehicle system is actuated and the battery is caused to operate to a high temperature state.

Further, a failure can be detected after a repair service is finished and before the vehicle is used, and therefore a failure can be detected earlier as compared to conventional failure detecting methods performing the failure detection while the battery is used.

Still further, by setting the timing for detecting a failure of a cooling fan to the timing when an auxiliary battery is replaced with a new one, detection is performed while ensuring the performance of the auxiliary battery to be the precondition for the failure detection. Accordingly, the accuracy of detecting a failure of the cooling fan can be improved and the performance of the cooling fan can be kept at a constant level.

Still further, by replacing the auxiliary battery with a new one utilizing the opportunity of the failure detection of the cooling fan, the performance of the cooling fan can be kept at a constant level.

Although the present invention has been described and illustrated in detail, it is clearly understood that the same is by way of illustration and example only and is not to be taken by way of limitation, the spirit and scope of the present invention being limited only by the terms of the appended claims.

1. A cooling device controlling apparatus controlling a cooling device for an electric unit mounted on a vehicle, said electric unit including a first power source, an electric power converter converting a direct current voltage of said first power source to drive a motor, and a second power source receiving a supply of electric power from said first power source to be charged, said cooling device controlling apparatus comprising:
cooling device control means for controlling a supply amount of a cooling medium of said cooling device based on temperature information of said electric unit; and
cooling device failure detect means for detecting a failure of said cooling device in accordance with initialization of said second power source.

2. The cooling device controlling apparatus according to claim 1, wherein
said cooling device failure detect means detects a failure of said cooling device after said second power source is replaced with a new second power source.

3. The cooling device controlling apparatus according to claim 1, wherein
said initialization of said second power source is initialization caused by replacement of said second power source.

4. The cooling device controlling apparatus according to claim 1, wherein
said cooling device control means includes
initialization determine means for determining whether or not said second power source is initialized,
mode command means for outputting to said cooling device a mode command specifying one mode selected out of a plurality of modes each specifying a supply amount, being different from one another, of said cooling medium based on a determination result of said initialization determine means and temperature information of said electric unit, and
timer means for measuring an output time period of said mode command, wherein
when said second power source is determined to be initialized, said mode command means selects a prescribed mode specifying a supply amount of said cooling medium required for determining a failure of said cooling device and outputs a command of said prescribed mode for a prescribed time period, and wherein
said cooling device failure detect means determines a failure of said cooling device based on whether or not a supply amount of a cooling medium of said cooling device is equal to a supply amount of said prescribed mode during said prescribed time period.

5. The cooling device controlling apparatus according to claim 4, wherein
said cooling device control means further includes
storage means for receiving a supply of electric power from said second power source to temporarily store information, and wherein
said initialization determine means determines that said second power source is initialized, based on loss of said information in said storage means.

6. The cooling device controlling apparatus according to claim 5, wherein
said cooling device includes
cooling medium generate means for generating said cooling medium in a supply amount specified by said mode command, and
generation amount detect means for detecting a generation amount of said cooling medium to transmit a detection result to said cooling device failure detect means.

7. The cooling device controlling apparatus according to claim 6, wherein
said initialization determine means determines, on actuation of said vehicle, whether or not said second power source is initialized.

8. The cooling device controlling apparatus according to claim 7, wherein
said cooling device receives a supply of electric power from said second power source to cool said electric unit.

9. A cooling device failure detecting apparatus detecting a failure of a cooling device cooling an electric unit mounted on a vehicle, said electric unit including a first power source, an electric power converter converting a direct current voltage of said first power source to drive a motor, and a second power source receiving a supply of electric power from said first power source to be charged, said cooling device failure detecting apparatus comprising:
initialization determine means for determining whether or not said second power source is initialized; and
failure detect means for detecting a failure of said cooling device in accordance with a determination that said second power source is initialized.

10. The cooling device failure detecting apparatus according to claim 9, wherein
said failure detect means detects a failure of said cooling device after said second power source is replaced with a new second power source.

11. The cooling device failure detecting apparatus according to claim 9, wherein
said second power source is replaced with a new second power source when a failure of said cooling device is detected.

12. The cooling device failure detecting apparatus according to claim 9, wherein
said initialization determine means determines that said second power source is initialized, based on loss of information temporarily stored with a supply of electric power from said second power source.

13. The cooling device failure detecting apparatus according to claim 12, wherein
said failure detect means includes
mode command means for outputting to said cooling device a mode command specifying one mode selected out of a plurality of modes each specifying a supply amount, being different from one another, of said cooling medium based on a determination result of said initialization determine means and temperature information of said electric unit, and
timer means for measuring a prescribed time period during which said mode command is output, wherein
when said second power source is determined to be initialized, said mode command means selects a prescribed mode specifying a supply amount of said cooling medium required for determining a failure of said cooling device and outputs a command of said prescribed mode for said prescribed time period, and wherein
said failure detect means further includes
failure determine means for determining a failure of said cooling device based on whether or not a supply amount of a cooling medium of said cooling device is equal to a supply amount of said prescribed mode during said prescribed time period.

14. The cooling device failure detecting apparatus according to claim 13, wherein
said initialization determine means determines, on actuation of said vehicle, whether or not said second power source is initialized.

15. The cooling device failure detecting apparatus according to claim 14, wherein
said cooling device receives a supply of electric power from said second power source to cool said electric unit.

16. A cooling device failure detecting method for detecting a failure of a cooling device cooling an electric unit mounted on a vehicle, said electric unit including a first power source, an electric power converter converting a direct current voltage of said first power source to drive a motor, and a second power source receiving a supply of electric power from said first power source to be charged, said cooling device failure detecting method comprising:
an initialization determine step of determining whether or not said second power source is initialized; and
a failure detect step of detecting a failure of said cooling device in accordance with a determination that said second power source is initialized.

17. The cooling device failure detecting method according to claim 16, wherein
said failure detect step includes a step of detecting a failure of said cooling device after said second power source is replaced with a new second power source.

18. The cooling device failure detecting method according to claim 16, further comprising
a step of replacing said second power source with a new second power source.

19. The cooling device failure detecting method according to claim 16, wherein
said initialization determine step includes a step of determining that said second power source is initialized, based on loss of information temporarily stored with a supply of electric power from said second power source.

20. The cooling device failure detecting method according to claim 19, wherein
said failure detect step includes
a mode command step of outputting to said cooling device a mode command specifying one mode selected out of a plurality of modes each specifying a supply amount, being different from one another, of said cooling medium based on a determination result of said initialization determine step and temperature information of said electric unit, and
a step of measuring a prescribed time period during which said mode command is output, wherein
said mode command step includes a step of selecting, when said second power source is determined to be initialized, a prescribed mode specifying a supply amount of said cooling medium required for determining a failure of said cooling device and outputting a command of said prescribed mode for said prescribed time period, and wherein
said failure detect step further includes
a failure determine step of determining a failure of said cooling device based on whether or not a supply amount of a cooling medium of said cooling device is equal to a supply amount of said prescribed mode during said prescribed time period.

21. The cooling device failure detecting method according to claim 20, wherein
said initialization determine step includes a step of determining, on actuation of said vehicle, whether or not said second power source is initialized.

22. The cooling device failure detecting method according to claim 21, wherein
said cooling device receives a supply of electric power from said second power source to cool said electric unit.

23. A computer readable recording medium recording a program for causing a computer to execute detection of a failure of a cooling device cooling an electric unit mounted on a vehicle, said electric unit including a first power source, an electric power converter converting a direct current voltage of said first power source to drive a motor, and a second power source receiving a supply of electric power from said first power source to be charged, said computer readable recording medium recording a program for causing a computer to execute:
an initialization determine step of determining whether or not said second power source is initialized; and
a failure detect step of detecting a failure of said cooling device in accordance with a determination that said second power source is initialized.

24. The computer readable recording medium recording a program for causing a computer to execute according to claim 23, wherein
said failure detect step includes a step of detecting a failure of said cooling device after said second power source is replaced with a new second power source.

25. The computer readable recording medium recording a program for causing a computer to execute according to claim 23, further causes the computer to execute
a step of replacing said second power source with a new second power source.

26. The computer readable recording medium recording a program for causing a computer to execute according to claim 23, wherein
said initialization determine step includes a step of determining that said second power source is initialized, based on loss of information temporarily stored with a supply of electric power from said second power source.

27. The computer readable recording medium recording a program for causing a computer to execute according to claim 26, wherein
said failure detect step includes
a mode command step of outputting to said cooling device a mode command specifying one mode selected out of a plurality of modes each specifying a supply amount, being different from one another, of said cooling medium based on a determination result of said initialization determine step and temperature information of said electric unit, and
a step of measuring a prescribed time period during which said mode command is output, wherein
said mode command step includes a step of selecting, when said second power source is determined to be initialized, a prescribed mode specifying a supply amount of said cooling medium required for determining a failure of said cooling device and outputting a command of said prescribed mode for said prescribed time period, and wherein
said failure detect step further includes
a failure determine step of determining a failure of said cooling device based on whether or not a supply amount of a cooling medium of said cooling device is equal to a supply amount of said prescribed mode during said prescribed time period.

28. The computer readable recording medium recording a program for causing a computer to execute according to claim 27, wherein
said initialization determine step includes a step of determining, on actuation of said vehicle, whether or not said second power source is initialized.

29. The computer readable recording medium recording a program for causing a computer to execute according to claim 28, wherein
said cooling device receives a supply of electric power from said second power source to cool said electric unit.
